(19) United States
(12) Patent Application Publication
(10) Pub. No.: US 2007/0001543 A1
(43) Pub. Date: Jan. 4, 2007

(54) Method and apparatus for electrically controlling the stroke of a mechanical member

(76) Inventors: Simon Powell, Hertfordshire (GB); George Perkins, Hants (GB); Pietro Mandurino, Bologna (IT)

Correspondence Address: Edward G Greive;Renner Kenner Greive Bobak Taylor & Weber, Fourth Floor First National Tower, Akron, OH, 44308-1456, US

(21) Appl. No.: 10/547,116

(22) PCT Filed: Feb. 25, 2004
(86) PCT No.: PCT/GB04/00746

§ 371 Date: Aug. 11, 2006

(30) Foreign Application Priority Data
Feb. 28, 2003 (GB) 0304669.5
May 31, 2003 (GB) 0311714.0

(51) Int. Cl. H01L 41/00

(52) U.S. Cl. 310/311

(57) ABSTRACT

A mechanical arrangement comprises a housing (10) arranged to receive an elongate member (11) which is mounted within the housing for reciprocation, the elongate member having an extension (11a) projecting outside the housing to form an output member, wherein the elongate member is formed with a shaped aperture (18) which receives an electrically actuated blocking member (19) which controls the stroke of the elongate member as it is moved towards and away from the elongate member in a direction transverse to the direction of reciprocation.

The present invention relates to a method and apparatus for controlling the stroke of a member in a mechanical arrangement and more particularly to providing proportional control.

There are many mechanical arrangements which utilise a linearly moveable member and it is often necessary to control the stroke of such a member. Further, there are known means for controlling the stroke of a member but most of these require changes to the mechanism itself and they are not suitable for combination with electrical control arrangements.

The present invention provides a mechanical arrangement where the stroke of a moveable member can be electrically controlled. Preferably the control is by means of a piezo ceramic actuator.

In order that the present invention be more readily understood, an embodiment thereof will now be described by way of example only with reference to the accompanying drawings in which:—

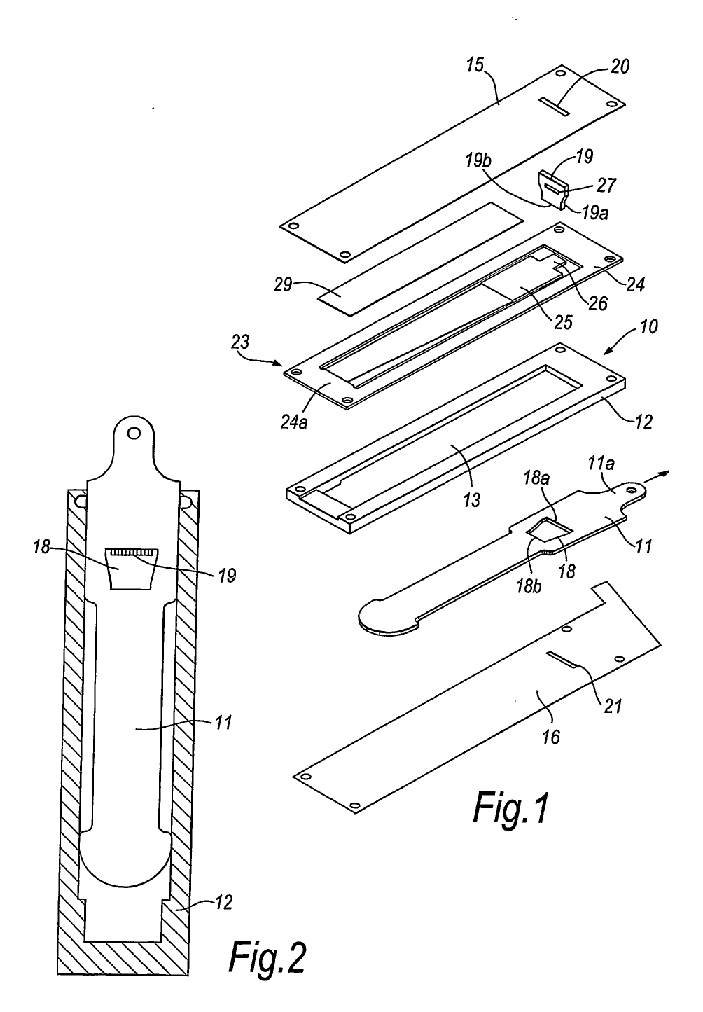

FIG. 1 shows an exploded perspective view of a mechanical arrangement having a moveable member the stroke of which is controlled;

FIG. 2 shows a sectional top view of the arrangement in FIG. 1; and

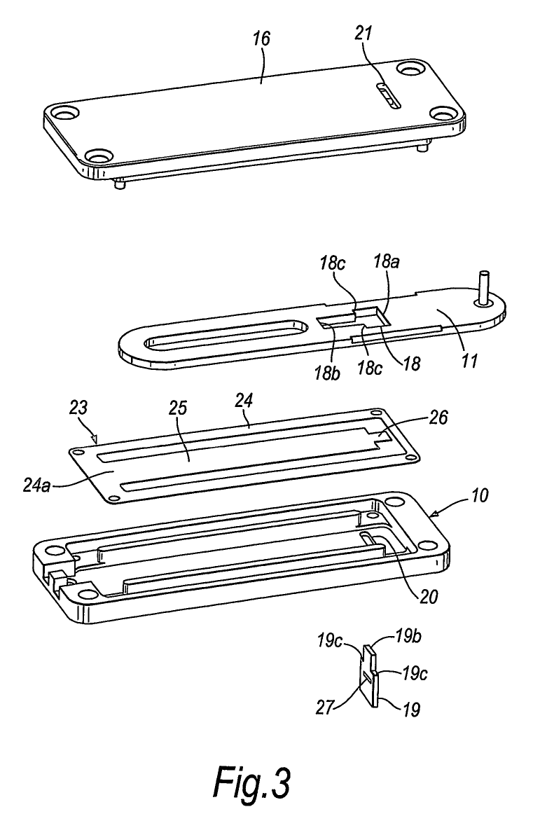

FIG. 3 shows an exploded perspective view of a modification of the arrangement shown in FIG. 1.

Referring to the drawings, it will be seen that the mechanism comprises a housing 10 and a member 11 which is linearly moveable with respect to the housing. In the present embodiment, the housing is basically rectangular and is made up of a number of planar elements. This is merely exemplary and the overall shape of the arrangement can change as can the shapes of the individual parts.

The housing 10 comprises a main body portion 12 in the form of a rectangular frame which defines a rectangular, elongate space 13 which is arranged to receive the moveable member 11. One end of the member 12 is provided with a slot or recess (not shown) which is arranged to receive an extension 11a of the moveable member 11. The extension 11a is the output of the mechanical arrangement in view of the fact that the moveable member 11 is arranged to move backwards and forwards along the length of the opening 13. The main member 12 is provided with top and bottom covers 15 and 16 respectively and the thus formed assembly is akin to a piston and cylinder device with the piston rod being the moveable member 11 and the cylinder formed by the housing 10. Thus far, the moveable member would simply slide up and down in the opening 13 in response to movement of a member attached to the extension 11a.

In order to control the amount of movement of the member 11, a shaped aperture 18 is formed in the member 11 which is arranged to receive a shaped key 19. The key 19 is retained in position by being located in slots 20 and 21 in the top and bottom covers 15,16 respectively. In this embodiment, the slots 20,21 are transverse to the direction of movement of the member 11. The key 19 has a portion 19a which tapers towards the end 19b of the key. The end 19b is a sliding fit in the slot 21. Due to the presence of the key 19, the maximum stroke of the member 11 with respect to the housing 10 is determined by the distance between the ends 18a and 18b of the aperture 18 in the member 11.

The present embodiment proposes to provide proportional control of the stroke of the member 11 by tapering the aperture 18 between the ends 8a and 8b. This taper in combination with the taper applied to the part 19a of the key will result in the stroke of the member 11 being controlled in accordance with the movement of the key in to and out of the aperture 18 ie in a direction transverse to the direction of movement of the member 11.

The movement of the key 19 is electrically controlled and the electrical control is achieved by means of a piezo ceramic actuator indicated generally by the reference numeral 23. The actuator 23 comprises a planar framework 24 attached to the main member 12 between the cover 15 and the main member 12. The frame 24 is provided with a tongue 25 which is cantilevered from one end 24a of the frame 24 and provided with a projection 26 which fits in a slot 27 in the key 19. The tongue is formed of a suitable metal which is provided with a layer 29 of piezo ceramic material, the energisation of which causes the tongue 25 to deflect and hence move the tapered portion 19a of the key 19 more or less into the slot 18. For simplicity, the electrical connections to the piezo ceramic layer 29 are not shown nor is the control circuit for applying the appropriate voltages to the ceramic layer in order to achieve the desired movement of the tongue 25.

With the above arrangement, it will be appreciated that the stroke of the member 11 can be proportionally controlled by appropriate electrical signals applied to the piezo ceramic layer 29 in order to position the key 19 appropriately having regard to the desired stroke of the member 11. It will be noted that the stroke of the member 11 is limited by the key 19 preventing movement of the member 11 beyond a point dictated by the taper on the portion 19a and the taper of the aperture 18. However, very few forces are transferred to the piezo ceramic actuator in view of the fact that the blocking forces are mainly provided by abutment of the key 19 in the slots 20 and 21.

The above arrangement is capable of providing an infinitely variable stroke within limits determined by the separation between the ends 18a and 18b of the aperture 18 but it will be appreciated that if stepwise changes are all that is required, then the shapes of the aperture 18 and/or the tapering portion 19a can be altered. It is thus a very simply matter to alter the operation.

Such a modification is shown in FIG. 3 where similar parts to those shown in FIG. 1 are given the same reference numerals and hence a detailed description of FIG. 3 will not be given.

The major difference between FIG. 3 and the arrangement shown in FIG. 1 is in the shape of the aperture 18 in the member 11 and also in the shape of the key 19. In the arrangement shown in FIG. 3 the aperture 18 is generally T-shaped with shoulders 18c at a junction between a narrow portion and the broader head of the aperture. Further, the key 19 is no longer tapered but is also formed with shoulders 19c between a main wider portion of the key 19 and a narrower, rectangular, portion 19b extending therefrom.

With this construction, and with the actuator in a suitable condition, eg energised, the narrow portion 19b of the key is positioned to permit the member 11 to slide from one end 18a of the slot 18 to the other end 18b in the narrow portion of the aperture. However, if the actuator is de-energised, the wider portion of the key 19 is present in the slot 18 and this restricts movement of the member 11 to be between the shoulders 18c and the end 18a.

The arrangement shown in FIG. 3 thus does not exhibit proportional control but rather a positive single stage control of movement of the member 11.

1. A mechanical arrangement comprising a housing arranged to receive an elongate member which is mounted within the housing for reciprocation, the elongate member having an extension projecting outside the housing to form an output member, wherein the elongate member is formed with a shaped aperture which receives an electrically actuated blocking member which controls the stroke of the elongate member as it is moved towards and away from the elongate member in a direction transverse to the direction of reciprocation.

2. An arrangement according to claim 1, wherein the aperture in the elongate reciprocating member tapers in the direction of reciprocation and the blocking member has a portion which tapers in the transverse direction.

3. An arrangement according to claim 1, wherein the aperture in the elongate reciprocating member is generally T-shaped and the blocking member has a main body portion with a rectangular extension arranged to be received in the aperture.

4. An arrangement according to claim 1, and comprising a piezo ceramic actuator for electrically actuating the blocking member.

5. An arrangement according to claim 1, wherein the housing is made from a plurality of substantially planar elements and the elongate reciprocating member is also planar.

6. (canceled)
